(19) United States
(12) Patent Application Publication
(10) Pub. No.: US 2020/0371421 A1
(43) Pub. Date: Nov. 26, 2020

(54) REFLECTIVE MASK BLANK, REFLECTIVE MASK AND METHOD FOR PRODUCING SAME, AND METHOD FOR PRODUCING SEMICONDUCTOR DEVICE

(71) Applicant: HOYA CORPORATION, Tokyo (JP)

(72) Inventors: Yohei IKEBE, Tokyo (JP); Takahiro ONOUE, Tokyo (JP)

(73) Assignee: HOYA CORPORATION, Tokyo (JP)

(21) Appl. No.: 16/763,742

(22) PCT Filed: Nov. 21, 2018
(86) PCT No.: PCT/JP2018/042942

§ 371 Date: May 13, 2020

(30) Foreign Application Priority Data
Nov. 27, 2017 (JP) 2017-226812

(51) Int. Cl. G03F 1/24; G03F 1/54; G03F 7/20; H01L 21/033

(52) U.S. Cl. CPC G03F 1/24; G03F 1/54; H01L 21/0337; H01L 21/0332; G03F 7/70033

(57) ABSTRACT

A reflective mask blank which is able to produce a reflective mask that is capable of forming a fine and highly accurate transfer pattern by further reducing the shadowing effects of the reflective mask. A reflective mask blank which sequentially comprises, on a substrate, a multilayer reflective film and an absorbent film in this order, and which is characterized in that the absorbent film is formed from a material that contains a first material which has a refractive index n of 0.99 or more for EUV light and a second material which has an extinction coefficient k of 0.035 or more for EUV light.

### CROSS-REFERENCE TO RELATED APPLICATIONS

This application is a National Stage of International Application No. PCT/JP2018/042942, filed on Nov. 21, 2018, which claims priority to Japanese Patent Application No. 2017-226812, filed Nov. 21, 2017, and the contents of which is incorporated by reference

### TECHNICAL FIELD

The present disclosure relates to a reflective mask blank that is an original plate for manufacturing an exposure mask for used for manufacturing a semiconductor device, a reflective mask, a method of manufacturing the same, and a method of manufacturing a semiconductor device.

### BACKGROUND ART

Types of light sources of an exposure apparatus in manufacturing semiconductor devices include a g-line having a wavelength of 436 nm, an i-line having a wavelength of 365 nm, a KrF laser having a wavelength of 248 nm, and an ArF laser having a wavelength of 193 nm. In order to achieve finer pattern transfer, the wavelengths of the light sources of the exposure apparatuses are gradually shortened. In order to achieve further finer pattern transfer, extreme ultra violet (EUV) lithography using EUV having a wavelength in the neighborhood of 13.5 nm has been developed. In EUV lithography, a reflective mask is used because there are few materials transparent to EUV light. The basic structure of this reflective mask is a structure in which a multilayer reflective film that reflects exposure light and a protective film for protecting the multilayer reflective film are formed on a low thermal expansion substrate, and a desired pattern for transfer is formed on the protective film. In addition, as typical examples of the reflective mask (reflection mask), a binary type reflection mask having a relatively thick absorber pattern (pattern for transfer) that sufficiently absorbs EUV light and a phase shift type reflection mask (half-tone phase shift type reflection mask) having a relatively thin absorber pattern (pattern for transfer) that reduces EUV light by light absorption and generates reflected light having a phase substantially inverted (phase inverted at approximately 180 degrees) with respect to reflected light from the multilayer reflective film. The phase shift type reflection mask (half-tone phase shift type reflection mask), like a transmission type optical phase shift mask, can obtain high transfer optical image contrast by a phase shift effect, so that a resolution can be improved. In addition, since the film thickness of an absorber pattern (phase shift pattern) of the phase shift type reflection mask is small, a fine phase shift pattern can be formed highly accurately.

In EUV lithography, a projection optical system including a large number of reflecting mirrors is used due to light transmittance. EUV light is made obliquely incident on the reflective mask, whereby these reflecting mirrors do not block projection light (exposure light). At present, an incident angle is typically 6 degrees with respect to the vertical plane of a reflection mask substrate, but with the improvement of a numerical aperture (NA) of the projection optical system, discussions are underway toward making the incident angle more oblique (about 8 degrees).

In EUV lithography, since the exposure light is obliquely incident, there is an inherent problem called a shadowing effect. The shadowing effect is a phenomenon in which a dimension and/or a position of a pattern that is transferred and formed change due to a shadow formed by exposure light being obliquely incident on an absorber pattern having a three-dimensional structure. The three-dimensional structure of the absorber pattern serves as a wall, forming a shadow on a shade side, and the dimension and/or the position of the pattern that is transferred and formed change. For example, due to a relationship between a direction of the absorber pattern to be arranged and an incident direction of oblique incident light, if the direction of the absorber pattern with respect to the incident direction of the oblique incident light is different, a difference occurs in the dimension and the position of the transfer pattern, and transfer accuracy decreases.

Patent Literatures 1 to 3 disclose techniques related to such a reflective mask for EUV lithography and a mask blank for manufacturing the same. In addition, Patent Literatures 1 and 2 disclose shadowing effects. Conventionally, it has been proposed to use a phase shift type reflection mask as a reflective mask for EUV lithography. In the case of the phase shift type reflection mask, the film thickness of the phase shift pattern can be made relatively thinner than the film thickness of the binary type reflection mask. Therefore, by using the phase shift type reflection mask, it is possible to suppress a decrease in transfer accuracy due to the shadowing effect.

### CITATION LIST

### Patent Literature

Patent Literature 1: JP 2010-080659 A
Patent Literature 2: JP 2004-207593 A
Patent Literature 3: JP 2004-39884 A

### DISCLOSURE OF THE INVENTION

The finer the pattern is and the higher the accuracy of the pattern dimension and pattern position is, the more the electrical characteristics and performance of the semiconductor device increase, the more the degree of integration can be improved, and the more the chip size can be reduced. Therefore, EUV lithography is required to have a pattern transfer performance of a finer dimension with a higher level of accuracy and a finer dimension than before. It is presently required to form an ultra-fine and highly accurate pattern for half pitch 16 nm (hp 16 nm) generation. In order to reduce the shadowing effect in response to such a demand, it is required to further reduce the thickness of the absorber pattern of the reflective mask. In particular, in the case of EUV exposure, the film thickness of an absorber film (phase shift film) is required to be less than 60 nm, and preferably 50 nm or less.

At the time of EUV exposure, exposure light from an EUV light source (also simply referred to as “light source”) is emitted to the reflective mask at a predetermined angle with respect to a vertical plane of the reflective mask via an illumination optical system. In the present description, exposure light emitted to the reflective mask may be referred to as “irradiation light”. Since the reflective mask has a predetermined absorber pattern, the irradiation light emitted to the absorber pattern (pattern for transfer) is absorbed, and the irradiation light emitted to a portion where the absorber pattern does not exist is reflected by the multilayer reflective film. As a result, a transfer-receiving substrate can be irradiated with the exposure light corresponding to the absorber pattern via a predetermined optical system.

FIGS. 4 to 6 show a state in which irradiation light (EUV exposure light) is emitted from a light source 20 to an irradiation area 50 of a reflective mask at a predetermined angle. FIG. 4 is a schematic plan diagram of the reflective mask diagramed from above. For description, FIG. 4 illustrates an X direction and a Y direction of the reflective mask. FIG. 5 is a schematic front diagram for illustrating a state in the X direction of FIG. 4. FIG. 6 is a schematic side diagram for illustrating a state in the Y direction of FIG. 4. FIGS. 4 to 6 are schematic diagrams for description, and are simplified by omitting an illumination optical system, a reduction projection optical system, and the like.

As shown in FIG. 5, the irradiation light emitted from the position of a point P of the light source 20 is emitted to the irradiation area 50 of a reflective mask 200 at a divergence angle θ_{d} (divergence angle). The divergence angle θ_{d} is the divergence of the irradiation light from a center irradiation light 30 that is the center of the irradiation light. That is, the divergence angle θ_{d} is half an irradiation angle of the entire irradiation light. As shown in FIGS. 4 to 6, the center irradiation light 30 is incident on a center C of the irradiation area of the reflective mask 200 from the point P at a predetermined angle θₓ₀. In the present description, when the reflective mask 200 is viewed from a direction parallel to a main surface thereof, a direction in which the center irradiation light 30 has a predetermined angle θₓ₀ (θₓ₀>0) is referred to as an X direction (see FIG. 5). In addition, in the present description, when the reflective mask 200 is viewed from the direction parallel to the main surface thereof, a direction in which the center irradiation light 30 is viewed as a vertical angle with respect to the reflective mask 200 is referred to as a Y direction (see FIG. 6). Therefore, as shown in the schematic plan diagram of FIG. 4, the light source 20 is displaced in the X direction and is not displaced in the Y direction. FIGS. 5 and 6, a virtual line perpendicular to a reflective mask surface is shown by a dashed line 40.

As shown in FIG. 5, the center irradiation light 30 from the point P of the light source 20 is incident on the reflective mask 200 at a predetermined angle θₓ₀. Therefore, irradiation light 31x and irradiation light 32x diverging in the X direction are incident on the reflective mask 200 at different incident angles θₓ₁ and θₓ₂, respectively. Usually, the angle θₓ₀ is about 6 to 8 degrees. For example, when a projection optical system having an NA of 0.33 is used, the divergence angle θ_{d} is about 5 degrees. Therefore, in the case of θₓ₀=6 degrees, the incident angle θₓ₁ of the irradiation light 31x is 1 degree and the incident angle θₓ₂ of the irradiation light 32x is 11 degrees. That is, the irradiation light from the light source 20 is incident on the reflective mask at an incident angle in the range of 1 to 11 degrees in the X direction. In the present description, an incident angle θₓ₀ of the center irradiation light 30 with respect to the reflective mask 200 may be simply referred to as “the incident angle of the irradiation light”.

Meanwhile, as shown in FIG. 6, in the Y direction, the center irradiation light 30 from the point P of the light source 20 is incident on the reflective mask 200 vertically (that is, at an incident angle of 0 degree). Also in this case, irradiation light 31y and irradiation light 32y diverging in the Y direction are incident on the reflective mask 200 at different incident angles θ_{y1} and θ_{y2}, respectively. For example, in the case of the projection optical system having an NA of 0.33, the divergence angle θ_{d} is about 5 degrees. Therefore, the incident angle θ_{y1} of the irradiation light 31y is −5 degrees and the incident angle θ_{y2} of the irradiation light 32y is +5 degrees. That is, the irradiation light from the light source 20 is incident on the reflective mask at an incident angle in the range of −5 to +5 degrees in the Y direction.

As described above, in a case where the incident angle of the irradiation light is 6 degrees, in the X direction, the irradiation light having an incident angle having a width centered at 6 degrees is incident on the reflective mask 200. In addition, in the Y direction, the irradiation light having an incident angle having a width corresponding to the divergence angle θ_{d} of the irradiation light is incident on the reflective mask 200.

The present inventors have found a problem that, in a case where the incident angle of the irradiation light with respect to the reflective mask 200 has a predetermined width as described above, a positional shift of a pattern and/or magnitude of the contrast differ for each angle. In addition, the present inventors have found that in the case of an absorber pattern having a three-dimensional structure, in particular, there is a problem that the positional shift of the pattern caused by a phase difference generated when irradiation light is transmitted through the absorber pattern increases. Note that since this problem can be considered to be a problem due to oblique incidence of the irradiation light, it can be said to be one of problems due to the shadowing effect of the reflective mask.

It is therefore an aspect of the present disclosure to provide a reflective mask blank capable of manufacturing a reflective mask capable of forming a fine and highly accurate transfer pattern on a transfer-receiving substrate by further reducing a shadowing effect of the reflective mask. In addition, another aspect of the present disclosure is to provide a reflective mask capable of forming a fine and highly accurate transfer pattern on a transfer-receiving substrate by further reducing the shadowing effect of the reflective mask. In addition, another aspect of the present disclosure is to provide a method of manufacturing a fine and highly accurate semiconductor device by using the mask for transfer described above.

The present inventors has found that, in order to solve the above-described problems, it is necessary to reduce a phase difference that occurs when irradiation light (EUV light) is transmitted through an absorber film used in the reflective mask (phase difference when compared with irradiation light transmitted through a vacuum). In the present description, this phase difference of the irradiation light transmitted through the absorber film when compared with the irradiation light transmitted through the vacuum may be simply referred to as the “phase difference of the absorber film”. In order to reduce the phase difference of the absorber film, it is conceivable to use a material having a refractive index n close to 1 in EUV light. An example of such a material is aluminum (Al). However, since Al has a small extinction coefficient k of approximately 0.03 in EUV light, it is difficult to reduce the thickness of the absorber film.

The present inventors have found that as a material of the absorber film, a material having a refractive index n close to 1 and a material having a large extinction coefficient k are combined, whereby it is possible to obtain an absorber film having a small phase difference thereof and capable of reducing the film thickness thereof, and reached the present disclosure.

In order to solve the above problems, the present disclosure has the following configurations.

(Configuration 1)

A configuration 1 of the present disclosure is a reflective mask blank having a multilayer reflective film and an absorber film in this order on a substrate, and the absorber film includes a material including a first material having a refractive index n of 0.99 or more for EUV light and a second material having an extinction coefficient k of 0.035 or more for EUV light.

According to the configuration 1 of the present disclosure, it is possible to obtain a reflective mask blank capable of manufacturing a reflective mask capable of forming a fine and highly accurate transfer pattern on a transfer-receiving substrate by further reducing a shadowing effect of the reflective mask.

(Configuration 2)

A configuration 2 of the present disclosure is the reflective mask blank of the configuration 1 in which a phase difference of EUV light transmitted through the absorber film when compared with EUV light transmitted through a vacuum is 150 degrees or less.

According to the configuration 2 of the present disclosure, a shadowing effect of a reflective mask caused by the phase difference of EUV light transmitted through the absorber film can be further reduced.

(Configuration 3)

A configuration 3 of the present disclosure is the reflective mask blank of the configuration 1 or 2 in which the refractive index n of the absorber film for EUV light is 0.955 or more, and the extinction coefficient k of the absorber film for EUV light is 0.03 or more.

According to the configuration 3 of the present disclosure, by appropriately controlling the phase difference and the extinction coefficient of the absorber film for EUV light, a shadowing effect is reduced, and the attenuation of EUV light emitted to an absorber pattern of the reflective mask can be increased.

(Configuration 4)

A configuration 4 of the present disclosure is the reflective mask blank according to any one of the configurations 1 to 3 in which the first material is a material containing at least one selected from aluminum (Al), germanium (Ge), and magnesium

(Mg).

According to the configuration 4 of the present disclosure, by using a predetermined material having a refractive index close to 1 as the first material, the phase difference of the absorber film for EUV light can be controlled to be an appropriate value.

(Configuration 5)

A configuration 5 of the present disclosure is the reflective mask blank according to any one of the configurations 1 to 4 in which the second material is a material containing at least one selected from nickel (Ni) and cobalt (Co).

Nickel (Ni) and cobalt (Co) have a high extinction coefficient, low toxicity compared to tellurium and the like, and have appropriate melting points compared to tin and the like. Therefore, by using a predetermined material as the second material, the extinction coefficient of the absorber film for EUV light can be controlled to be an appropriate value.

(Configuration 6)

A configuration 6 of the present disclosure is the reflective mask blank according to any one of the configurations 1 to 5 in which the first material is aluminum (Al), and the content of the aluminum (Al) in the absorber film is 10 to 90 atomic %.

Aluminum has a refractive index for EUV light closer to 1 than other metals. By using aluminum as the first material as in the configuration 6 of the present disclosure, the phase difference of the absorber film for EUV light can be controlled to be a more appropriate value.

(Configuration 7)

A configuration 7 of the present disclosure is a reflective mask having an absorber pattern in which the absorber film in the reflective mask blank according to any one of the configurations 1 to 6 is patterned.

According to the configuration 7 of the present disclosure, since a shadowing effect of the reflective mask can be further reduced, it is possible to obtain a reflective mask capable of forming a fine and highly accurate transfer pattern on a transfer-receiving substrate.

(Configuration 8)

A configuration 8 of the present disclosure is a method of manufacturing a reflective mask in which the absorber film of the reflective mask blank according to any one of the configurations 1 to 6 is patterned by dry etching to form an absorber pattern.

According to the configuration 8 of the present disclosure, it is possible to further reduce a shadowing effect and it is possible to manufacture a reflective mask capable of forming a fine and highly accurate transfer pattern on a transfer-receiving substrate.

(Configuration 9)

A configuration 9 of the present disclosure is a method of manufacturing a semiconductor device that includes a step of setting the reflective mask of the configuration 7 in an exposure apparatus having an exposure light source that emits EUV light and transferring a transfer pattern to a resist film formed on a transfer-receiving substrate.

According to the configuration 9 of the present disclosure, it is possible to manufacture a fine and highly accurate method of manufacturing a semiconductor device.

According to the present disclosure, by further reducing the shadowing effect of the reflective mask, it is possible to provide a reflective mask blank capable of manufacturing a reflective mask capable of forming a fine and highly accurate transfer pattern on a transfer-receiving substrate. In addition, according to the present disclosure, by further reducing the shadowing effect of the reflective mask, it is possible to provide a reflective mask capable of forming a fine and highly accurate transfer pattern on a transfer-receiving substrate. In addition, according to the present disclosure, by using a mask for transfer, it is possible to provide a fine and highly accurate method of manufacturing a semiconductor device.

### BRIEF DESCRIPTION OF DRAWINGS

FIG. 1 is a schematic cross-sectional diagram of a main part for describing a schematic configuration of a reflective mask blank of the present disclosure.

FIGS. 2A-2D are step diagrams showing, in a schematic cross-sectional diagram, a main part of a step of manufacturing a reflective mask from a reflective mask blank.

FIG. 3 is a graph showing characteristics of a refractive index n and an extinction coefficient k of a metal material in EUV light (wavelength: 13.5 nm).

FIG. 4 is a schematic plan diagram showing a state in which irradiation light is emitted from an exposure light source to the reflective mask at a predetermined center angle θₓ₀ in an X direction.

FIG. 5 is a schematic front diagram in the X direction showing a state in which irradiation light is emitted from the exposure light source to the reflective mask at the center angle θₓ₀.

FIG. 6 is a schematic side diagram in the Y direction showing a state in which irradiation light is emitted from an exposure light source to a reflective mask at the center angle θₓ₀.

FIG. 7 is a schematic cross-sectional diagram showing a state in which irradiation light is transmitted through an edge of an absorber pattern of the reflective mask.

### DESCRIPTION OF EMBODIMENTS

Hereinafter, an embodiment of the present disclosure will be specifically described with reference to the drawings. Note that the following embodiment is one mode for embodying the present disclosure, and does not limit the present disclosure within the scope thereof. Note that in the drawings, the same or corresponding portions are denoted by the same reference signs, and description thereof may be simplified or omitted.

In addition, in the present description, “on” a substrate or film includes not only a case of being in contact with the top surface of the substrate or film but also a case of being not in contact with the top surface of the substrate or film. That is, “on” a substrate or a film includes cases such as a case where a new film is formed above the substrate or the film and a case where another film is interposed between the substrate or the film and a thing “on” the substrate or the film. In addition, “on” does not necessarily mean an upper side in a vertical direction, but merely indicates a relative positional relationship of a substrate, a film, and the like.

<Configuration of Reflective Mask Blank and Method of Manufacturing the Same>

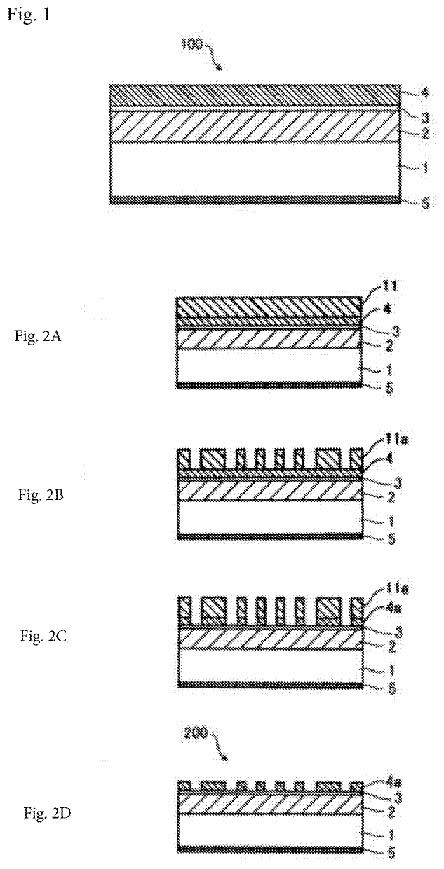

FIG. 1 is a schematic cross-sectional diagram of a main part of a schematic configuration of an example of a mask blank 100 of the present embodiment. The present embodiment is the reflective mask blank 100 having a multilayer reflective film 2 and an absorber film 4 in this order on a substrate 1. As described below, the reflective mask blank 100 of the present embodiment can have a film other than the substrate 1, the multilayer reflective film 2, and the absorber film 4. For example, the mask blank 100 shown in FIG. 1 has a protective film 3 and a back surface conductive film 5. As shown in FIG. 2D, an absorber pattern 4a of a reflective mask 200 is formed by patterning the absorber film 4 of the reflective mask blank 100.

Hereinafter, each layer will be described.

<<Substrate>>

As the substrate 1, a substrate having a low thermal expansion coefficient in the range of 0±5 ppb/° C. is preferably used in order to prevent distortion of the absorber pattern 4a due to heat during exposure to EUV light. Examples of a usable material having a low thermal expansion coefficient in this range include SiO₂—TiO₂-based glass and multicomponent glass ceramics.

In view of obtaining at least pattern transfer accuracy and position accuracy, a first main surface on a side of the substrate 1 where a transfer pattern (formed by the absorber film 4 to be described later) is formed has been subjected to a surface treatment so as to have high flatness. In the case of EUV exposure, flatness in an area having a size of 132 mm×132 mm of a main surface on a side of the substrate 1 where the transfer pattern is formed is preferably 0.1 μm or less, more preferably 0.05 μm or less, still more preferably 0.03 μm or less. In addition, a second main surface opposite to the first main surface is a surface to be electrostatically chucked when set in an exposure apparatus. Flatness in an area having a size of 132 mm×132 mm of the second main surface is preferably 0.1 μm or less, more preferably 0.05 μm or less, and still more preferably 0.03 μm or less. Note that flatness in an area of 142 mm×142 mm on a side of the second main surface in the reflective mask blank 100 is preferably 1 μm or less, more preferably 0.5 μm or less, and still more preferably 0.3 μm or less.

In addition, high surface smoothness of the substrate 1 is also an extremely important item. Surface roughness of the first main surface on which the absorber pattern 4a for transfer is formed preferably has a root mean square roughness (RMS) of 0.1 nm or less. Note that the surface smoothness can be measured with an atomic force microscope.

Furthermore, the substrate 1 preferably has high rigidity in order to prevent deformation due to a film stress applied on a film (such as the multilayer reflective film 2) formed on the substrate 1. In particular, the substrate 1 preferably has a high Young's modulus of 65 GPa or more.

<<Multilayer Reflective Film>>

The multilayer reflective film 2 provides the reflective mask 200 with a function that reflects EUV light. The multilayer reflective film 2 has a structure of a multilayer film in which layers mainly containing elements having different refractive indexes are periodically layered.

Generally, as the multilayer reflective film 2, a multilayer film in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods. The multilayer film may be formed by counting, as one period, a stack of a high refractive index layer and a low refractive index layer in which the high refractive index layer and the low refractive index layer are layered in this order from the substrate 1 and building up a plurality of periods of the stack. Alternatively, the multilayer film may be formed by counting, as one period, a stack of a low refractive index layer and high refractive index layer in which the low refractive index layer and the high refractive index layer are layered in this order from the substrate 1 and building up the stack for a plurality of periods. Note that a layer of the outermost surface of the multilayer reflective film 2 (that is, a surface layer of the multilayer reflective film 2 on a side opposite to the substrate 1) is preferably a high refractive index layer. In the multilayer film described above, in a case where a stack (high refractive index layer and low refractive index layer) in which a high refractive index layer and a low refractive index layer are layered in this order on the substrate 1 is counted as one period and the stack is built up for a plurality of periods, the uppermost layer is a low refractive index layer. Since the low refractive index layer of the outermost surface of the multilayer reflective film 2 is easily oxidized, a reflectance of the multilayer reflective film 2 decreases. In order to avoid a decrease in the reflectance, it is preferable to further form a high refractive index layer on the low refractive index layer that is the uppermost layer to form the multilayer reflective film 2. Meanwhile, in the multilayer film described above, in a case where a stack (low refractive index layer and high refractive index layer) in which the low refractive index layer and the high refractive index layer are layered in this order from the substrate 1 is counted as one period and the stack is built up for a plurality of periods, the uppermost layer is a high refractive index layer. In this case, there is no need to further form a high refractive index layer.

In the present embodiment, a layer containing silicon (Si) is employed as the high refractive index layer. As a material containing Si, in addition to Si alone, an Si compound containing Si and boron (B), carbon (C), nitrogen (N), and/or oxygen (O) can be used. By using the layer containing Si as the high refractive index layer, the reflective mask 200 for EUV lithography having an excellent EUV light reflectance can be obtained. In addition, in the present embodiment, a glass substrate is preferably used as the substrate 1. Si also has excellent adhesion to the glass substrate. In addition, as the low refractive index layer, metal alone selected from molybdenum (Mo), ruthenium (Ru), rhodium (Rh), and platinum (Pt), or an alloy thereof is used. For example, as the multilayer reflective film 2 for EUV light having a wavelength of 13 nm to 14 nm, an Mo/Si periodic layered film in which an Mo film and an Si film are alternately layered for about 40 to 60 periods is preferably used. Note that a high refractive index layer that is the uppermost layer of the multilayer reflective film 2 can be formed using silicon (Si), and a silicon oxide layer containing silicon and oxygen can be formed between the uppermost layer (Si) and a Ru-based protective film 3. By forming the silicon oxide layer, the cleaning resistance of the reflective mask 200 can be improved.

A reflectance of the multilayer reflective film 2 alone is usually 65% or more, and the upper limit thereof is usually 73%. Note that the thickness and period of each constituent layer of the multilayer reflective film 2 can be appropriately selected depending on an exposure wavelength, and can be selected so as to satisfy, for example, the Bragg's reflection law. In the multilayer reflective film 2, there are a plurality of high refractive index layers and a plurality of low refractive index layers. The thicknesses of the plurality of high refractive index layers does not need to be the same, and the thicknesses of the plurality of low refractive index layers need not be the same. In addition, the film thickness of the Si layer of the outermost surface of the multilayer reflective film 2 can be adjusted within a range that does not lower the reflectance. The film thickness of the Si (high refractive index layer) of the outermost surface can be 3 nm to 10 nm.

A method of forming the multilayer reflective film 2 is publicly known in this technical field. For example, the multilayer reflective film 2 can be formed by forming a film of each layer of the multilayer reflective film 2 by an ion beam sputtering method. In the case of the above-described Mo/Si periodic multilayer film, for example, by an ion beam sputtering method, first, a Si film having a thickness of about 4 nm is formed on the substrate 1 using an Si target, and then an Mo film having a thickness of 3 nm is formed using an Mo target. With the Si film and the Mo film counted as one period, the Si film and the Mo film are layered for 40 to 60 periods to form the multilayer reflective film 2 (a layer of the outermost surface is an Si layer). In addition, when the multilayer reflective film 2 is formed, it is preferable to form the multilayer reflective film 2 by supplying krypton (Kr) ion particles from an ion source and performing ion beam sputtering.

<<Protective Film>>

The protective film 3 is formed on the multilayer reflective film 2 in order to protect the multilayer reflective film 2 from dry etching and/or cleaning in a step of manufacturing the reflective mask 200 to be described later. In addition, when a black defect of the absorber pattern 4a is corrected using an electron beam (EB), the multilayer reflective film 2 can be protected by the protective film 3. FIG. 1 shows a case where the protective film 3 is one layer. The protective film 3 can have a stack of three or more layers. For example, the protective film 3 can have a structure in which the lowermost layer and the uppermost layer of the protective film 3 are layers including a substance containing Ru, and metal other than Ru or an alloy of metal other than Ru is interposed between the lowermost layer and the uppermost layer. A material of the protective film 3 includes, for example, a material containing ruthenium as a main component. As the material containing ruthenium as a main component, Ru metal alone and a Ru alloy containing contains Ru and metal such as titanium (Ti), niobium (Nb), molybdenum (Mo), zirconium (Zr), yttrium (Y), boron (B), lanthanum (La), cobalt (Co), and/or rhenium (Re) can be used. In addition, these materials of the protective film 3 can further contain nitrogen. The protective film 3 is effective in a case where the absorber film 4 is patterned by dry etching of a Cl-based gas.

In a case where a Ru alloy is used as the material of the protective film 3, a Ru content ratio of the Ru alloy is 50 atomic % or more and less than 100 atomic %, preferably 80 atomic % or more and less than 100 atomic %, more preferably 95 atomic % or more and less than 100 atomic %. In particular, in a case where the Ru content ratio of the Ru alloy is 95 atomic % or more and less than 100 atomic %, the EUV light reflectance can be secured sufficiently while the diffusion of the element (silicon) constituting the multilayer reflective film 2 to the protective film 3 is suppressed. Furthermore, this protective film 3 can have mask cleaning resistance, an etching stopper function when the absorber film 4 is etched, and a protective function for preventing the multilayer reflective film 2 from changing over time.

In the case of EUV lithography, since there are few substances that are transparent to exposure light, it is not technically easy to apply an EUV pellicle that prevents a foreign matter from adhering to a mask pattern surface. For this reason, pellicle-less operation without using a pellicle has been the mainstream. In addition, in the case of EUV lithography, exposure contamination such as carbon film deposition on a mask or an oxide film growth by EUV exposure occurs. Therefore, it is necessary to frequently clean and remove foreign matters and contamination on a mask at a stage where the EUV reflective mask 200 is used for manufacturing a semiconductor device. For this reason, the EUV reflective mask 200 is required to have extraordinary mask cleaning resistance as compared with a transmissive mask for optical lithography. With the use of the Ru-based protective film 3 containing Ti, cleaning resistance to cleaning liquids such as sulfuric acid, sulfuric acid peroxide (SPM), ammonia, ammonia peroxide (APM), hydroxyl (OH) radical cleaning water, and ozone water having a concentration of 10 ppm or less can be particularly high. Therefore, it is possible to satisfy the requirement of the mask cleaning resistance for the EUV reflective mask 200.

The thickness of the protective film 3 is not particularly limited as long as the function of the protective film 3 can be achieved. From the viewpoint of the EUV light reflectance, the thickness of the protective film 3 is preferably 1.0 nm to 8.0 nm, and more preferably 1.5 nm to 6.0 nm.

As a method of forming the protective film 3, it is possible to adopt a film forming method similar to a publicly known one without any particular limitation. Specific examples of the method of forming the protective film 3 include a sputtering method and an ion beam sputtering method.

<<Absorber Film>>

The absorber film 4 that absorbs EUV light is formed on the protective film 3. A material of the absorber film 4 needs to be a material that has a function that absorbs EUV light and can be processed by dry etching.

The absorber film 4 of the present embodiment includes a material including a first material having a refractive index n of 0.99 or more for EUV light and a second material having an extinction coefficient k of 0.035 or more for EUV light.

The present inventors has found that, in order to further reduce a shadowing effect of the reflective mask 200, it is necessary to reduce a phase difference of the absorber film 4 used in the reflective mask 200, that is, a phase difference generated in the exposure light (irradiation light) transmitted through the absorber film 4 when compared with exposure light transmitted through a vacuum.

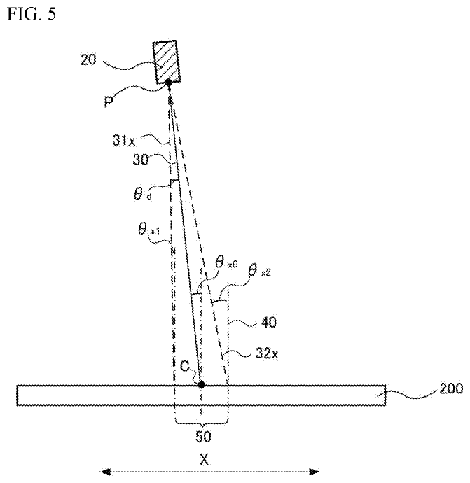

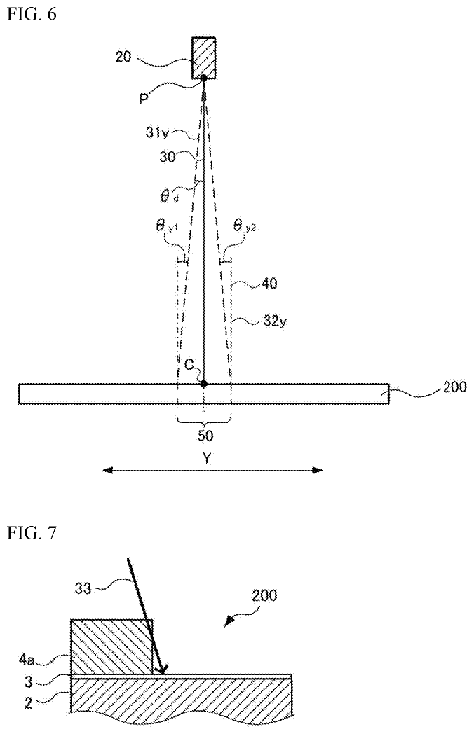

As shown in FIG. 5, a center irradiation light 30 from a point P of a light source 20 is incident on the reflective mask 200 at a predetermined angle θₓ₀ (normally, θₓ₀=about 6 degrees). For example, in the case of a projection optical system having an NA of 0.33, since a divergence angle θ_{d} is about 5 degrees, an incident angle θₓ₁ of irradiation light 31x is 1 degree and the incident angle θₓ₂ of irradiation light 32x is 11 degrees. That is, the irradiation light from the light source 20 has an incident angle in the range of 1 to 11 degrees in an X direction. In a case where the irradiation light 32x is incident on the edge of the absorber pattern 4a at an incident angle θₓ₂ (=11 degrees), the irradiation light 32x is transmitted through the edge of the absorber pattern 4a, whereby a phase may be shifted as compared with light that is not transmitted through the absorber pattern 4a (transmitted light transmitted through the vacuum). FIG. 7 shows a state in which irradiation light 33 is transmitted through the edge of the absorber pattern 4a of the reflective mask 200. As a result, a phase difference occurs between the transmitted light that is not transmitted through the absorber pattern 4a and the transmitted light that is transmitted through the absorber pattern 4a, and interference of the transmitted light occurs at the edge of the absorber pattern 4a. As a result, contrast at the edge of the absorber pattern 4a may be reduced. In addition, in a case where the irradiation light 31x is incident on the edge of the absorber pattern 4a at the incident angle θₓ₁ (=1 degree), the irradiation light 31x is transmitted through the absorber pattern 4a over a predetermined length. There is a large difference between a length at which the irradiation light 31x is transmitted through the absorber pattern 4a at the incident angle of 1 degree and a length at which the irradiation light 32x is transmitted through the absorber pattern 4a in a case where the irradiation light 32x is incident on the edge of the absorber pattern 4a at the incident angle θₓ₂ (=11 degrees). As a result, a positional shift of the absorber pattern 4a occurs for each incident angle.

On the basis of the above findings, the present inventors have found the following. That is, the refractive index n of the absorber film 4 for forming the absorber pattern 4a for EUV light is close to n=1 (refractive index of the vacuum), whereby a phase shift of the transmitted light transmitted through the absorber pattern 4a can be reduced regardless of a length at which the irradiation light is transmitted through the absorber pattern 4a. Therefore, a change in contrast at the edge of the absorber pattern 4a and/or a positional shift of the pattern can be suppressed. As a result, the shadowing effect of the reflective mask 200 can be further reduced.

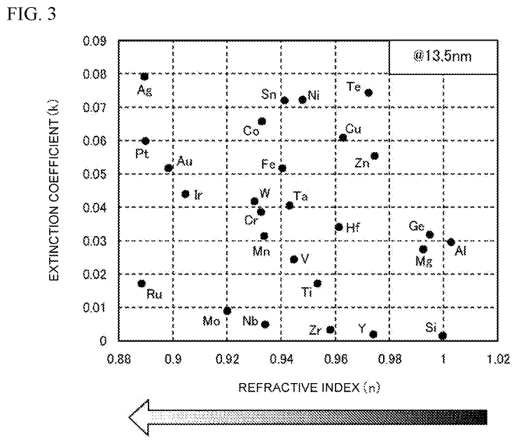

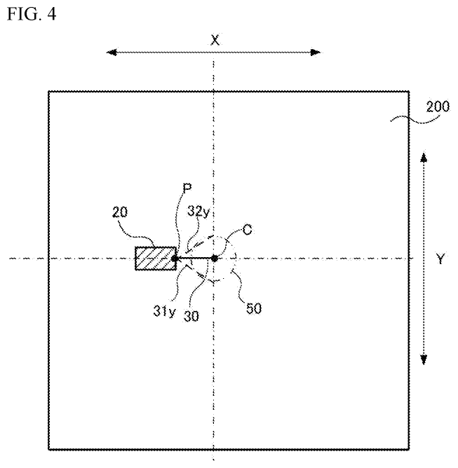

Meanwhile, in order for the reflective mask 200 to function as the absorber pattern 4a, the extinction coefficient k for EUV light needs to be high. FIG. 3 is a graph showing a relationship between the refractive index n of the metal material and the extinction coefficient k in EUV light (wavelength 13.5 nm). As shown in FIG. 3, there is no material having a refractive index n for EUV light close to 1 and a high extinction coefficient k for EUV light.

On the basis of the above findings, the present inventors have found that it is possible to form the absorber film 4 capable of suppressing a change in contrast at the edge of the absorber pattern 4a, by using a material obtained by combining the first material having the refractive index n for EUV light close to 1 and the second material having the high extinction coefficient k for EUV light, and reached the present disclosure. According to the present disclosure, the shadowing effect of the reflective mask 200 can be further reduced.

The refractive index n of the first material for EUV light is 0.99 or more, and preferably 0.99 or more and 1.01 or less. Specifically, examples of the first material include aluminum (Al), germanium (Ge), magnesium (Mg), silicon (Si), and an alloy of two or more kinds thereof.

The first material is preferably a material containing at least one selected from aluminum (Al), germanium (Ge), and magnesium (Mg). As shown in FIG. 3, refractive indexes n of aluminum (Al), germanium (Ge), and magnesium (Mg) for EUV light are relatively close to n=1, and extinction coefficients k thereof are relatively high. Therefore, by using a material containing at least one selected from aluminum (Al), germanium (Ge), and magnesium (Mg) as the first material, the phase difference of the absorber film 4 for EUV light can be controlled to be an appropriate value.

In order to make the refractive index n of the absorber film 4 for EUV light close to 1, the content of the first material in the absorber film 4 is preferably 10 to 90 atomic %, and more preferably 30 to 90 atomic %.

The first material is preferably aluminum (Al) or an alloy containing aluminum (Al). In addition, it is more preferable that the first material is more preferably a material substantially including aluminum (Al) and excluding impurities that are unavoidably mixed. As shown in FIG. 3, since the refractive index n of aluminum (Al) for EUV light is 1 or more, even in a case where a material having a relatively low refractive index n is selected as the second material, the absorber film 4 having a relatively low refractive index n can be obtained. In addition, in the reflective mask blank 100 of the present embodiment, the first material is preferably aluminum (Al), and the content of aluminum (Al) in the absorber film 4 is preferably 10 to 90 atomic %. By using aluminum at a predetermined content as the first material, the phase difference of the absorber film 4 for EUV light can be controlled to be a more appropriate value.

The preferred content of the first material in the absorber film 4 differs according to a value of the extinction coefficient k of the second material. The details are as follows. That is, when the extinction coefficient k of the second material is 0.035 or more and less than 0.05, the content of the first material in the absorber film 4 is preferably 30 to 90 atomic %. In addition, when the extinction coefficient k of the second material is 0.05 or more and less than 0.065, the content of the first material in the absorber film 4 is preferably 20 to 90 atomic %. In addition, when the extinction coefficient k of the second material is 0.065 or more, the content of the first material in the absorber film 4 is preferably 10 to 90 atomic %. In these cases, the first material is preferably aluminum (Al) or an alloy containing aluminum (Al).

The extinction coefficient k of the second material for EUV light is 0.035 or more, preferably 0.05 or more, and more preferably 0.065 or more. Specifically, examples of a second material having an extinction coefficient k of 0.035 or more include an alloy of one kind or two or more kinds selected from silver (Ag), tellurium (Te), nickel (Ni), tin (Sn), cobalt (Co), copper (Cu), platinum (Pt), zinc (Zn), iron (Fe), gold (Au), iridium (Ir), tungsten (W), tantalum (Ta) and chromium (Cr). In addition, examples of a second material having an extinction coefficient k of 0.05 or more include an alloy of one kind or two or more kinds selected from silver (Ag), tellurium (Te), nickel (Ni), tin (Sn), cobalt (Co), copper (Cu), and platinum (Pt), zinc (Zn), iron (Fe), and gold (Au). In addition, examples of a second material having an extinction coefficient k of 0.065 or more include an alloy of one kind or two or more kinds selected from silver (Ag), tellurium (Te), nickel (Ni), tin (Sn), and cobalt (Co).

The second material is preferably a material having a higher refractive index n in addition to an extinction coefficient k for EUV light being equal to or higher than a predetermined value. Specifically, the refractive index n of the second material for EUV light is preferably 0.92 or more, and more preferably 0.93 or more. Considering that the second material is a material having a higher refractive index n, it is preferable that the second material is specifically an alloy of one kind or two or more kinds selected from tellurium (Te), nickel (Ni), tin (Sn), and cobalt (Co).

Considering that tellurium (Te) is toxic and the melting point of tin (Sn) is too low, the second material is more preferably a material containing at least one selected from nickel (Ni) and cobalt (Co). In addition, it is more preferable that the second material is a material substantially including at least only one selected from nickel (Ni) and cobalt (Co) and excluding impurities that are unavoidably mixed.

The material of the absorber film 4 can include materials other than the first material and the second material described above. For example, the material of the absorber film 4 can include at least one kind selected from Ru, Ti, and Si. In order not to hinder the effects of the present disclosure, the content of materials other than the first material and the second material contained in the material of the absorber film 4 is preferably 5 atomic % or less.

The material of the absorber film 4 can be a compound of the above-described metal materials of the first material and the second material. Specifically, the first material and the second material can include, for example, one kind selected from nitrogen (N), oxygen (O), carbon (C), and boron (B). In order not to hinder the effects of the present disclosure, the content of materials other than metal of the first material and the second material included in the material of the absorber film 4 (for example, nitrogen (N), oxygen (O), carbon (C), and boron (B)) is preferably 5 atomic % or less.

In order to obtain the absorber film 4 having a refractive index for EUV light close to 1 and a high extinction coefficient k for EUV light, it is preferable that the first material is aluminum (Al) and the second material is nickel (Ni), cobalt (Co), or an alloy of nickel (Ni) or cobalt (Co). Therefore, the material of the absorber film 4 of the mask blank of the present embodiment is preferably AlNi, AlCo, or AlNiCo.

The material of the absorber film 4 includes the above-described first material and second material, whereby the shadowing effect of the reflective mask 200 can be further reduced. Therefore, by using the reflective mask 200 manufactured using the reflective mask blank 100 of the present embodiment, a fine and highly accurate transfer pattern can be formed on a transfer-receiving substrate 1.

In the reflective mask blank 100 of the present embodiment, the phase difference of the EUV light transmitted through the absorber film 4 when compared with EUV light transmitted through the vacuum is preferably 150 degrees or less and more preferably 90 degrees or less. Note that “EUV light transmitted through the absorber film 4” refers to EUV light incident on a surface of the absorber film 4 from a normal line direction. “EUV light transmitting through the vacuum” refers to EUV light transmitted through the vacuum in an optical path similar to that of “EUV light transmitted through the absorber film 4”. The phase difference of the EUV light transmitted through the absorber film 4 is within a predetermined range, whereby the shadowing effect of the reflective mask 200 due to the phase difference of the absorber film 4 with respect to the EUV light can be further reduced.

In the reflective mask blank 100 of the present embodiment, the refractive index n of the absorber film 4 for EUV light is preferably 0.955 or more and more preferably 0.975 or more. In addition, in the reflective mask blank 100 of the present embodiment, the extinction coefficient k is preferably 0.03 or more and more preferably 0.05 or more. By appropriately controlling the phase difference and the extinction coefficient of the absorber film 4 with respect to the EUV light, the shadowing effect can be reduced, and the attenuation of EUV light emitted to the absorber film 4 can be increased.

The absorber film 4 of the present embodiment can be formed by a publicly known method such as a direct current sputtering method or a magnetron sputtering method such as a radio frequency sputtering method. In addition, as a target, an alloy target of the first material and the second material can be used. In addition, as the target, a target of the first material and a target of the second material can be used.

The absorber film 4 is preferably an absorber film 4 for the purpose of absorbing EUV light as the reflective mask blank 100 of a binary type.

In the case of the absorber film 4 for the purpose of absorbing EUV light, the film thickness thereof is set so that the EUV light reflectance to the absorber film 4 is 2% or less and preferably 1% or less. In addition, in order to further suppress the shadowing effect, the film thickness of the absorber film 4 is preferably less than 60 nm and more preferably 50 nm or less.

The absorber film 4 may be a single layer film or a multilayer film including two or more films. In the case of a single layer film, the number of steps at the time of manufacturing the mask blank can be reduced and production efficiency is increased. In the case of a multilayer film, an optical constant and film thickness of an upper layer film can be appropriately set so that the upper layer film serves as an antireflection film at the time of a mask pattern inspection using light. This improves inspection sensitivity at the time of the mask pattern inspection using light. In this manner, by making the absorber film 4 a multilayer film, various functions can be added.

The absorber film 4 can be formed of a material of AlNi, AlCo, or AlNiCo. As an etching gas for the absorber film 4 of these materials, it is possible to use a chlorine-based gas such as Cl₂, SiCl₄, CHCl₃, and CCl₄, a mixed gas containing a chlorine-based gas and He at a predetermined ratio, a mixed gas containing a chlorine-based gas and Ar at a predetermined ratio, and the like.

In addition, in the case of the absorber film 4 having a two-layer structure, an etching gas may be different between an upper layer film and a lower layer film. For example, as the etching gas for the upper layer film, it is possible to use one selected from a fluorine-based gas such as CF₄, CHF₃, C₂F₆, C₃F₆, C₄F₆, C₄F₈, CH₂F₂, CH₃F, C₃F₈, SF₆, and F₂, a mixed gas containing a fluorine-based gas and O₂ at a predetermined ratio, and the like. In addition, as the etching gas for the lower layer film, it is possible to use one selected from a chlorine-based gas such as Cl₂, SiCl₄, and CHCl₃, a mixed gas containing a chlorine-based gas and O₂ at a predetermined ratio, a mixed gas containing a chlorine-based gas and He at a predetermined ratio, and a mixed gas containing a chlorine-based gas and Ar at a predetermined ratio. Here, an etching gas containing oxygen in the final stage of etching causes surface roughness of the Ru-based protective film 3. For this reason, it is preferable to use an etching gas that does not contain oxygen in an over-etching stage in which the Ru-based protective film 3 is exposed to etching.

In a case where the absorber film 4 has a two-layer structure, one layer can be of a metal alloy of the first material and the second material, and the other layer can be of a compound of the metal materials of the first material and the second material (for example, a compound with at least one kind selected from nitrogen (N), oxygen (O), carbon (C), and boron (B). For example, the lower layer film of the two-layer structure can be formed using AlNi, and the upper layer film can be formed using AlNiO.

The absorber film 4 can have a multilayer structure. In this case, the absorber film 4 can have a structure in which a plurality of layers of two different kinds of materials is alternately built up. For example, one layer of the layers of the two different kinds of materials can be of a metal alloy of the first material and the second material, and the other layer can be of a compound of metal materials of the first material and the second material (for example, a compound with at least one kind selected from nitrogen (N), oxygen (O), carbon (C), and boron (B)), a stack formed of the one layer and the other layer is counted as one period, and a film obtained by building up the stack for a plurality of periods is used as the absorber film 4.

<<Etching Mask Film>>

An etching mask film may be formed on the absorber film 4. As a material of the etching mask film, a material having a high etching selective ratio of the absorber film 4 to the etching mask film is used. Here, “an etching selective ratio of B to A” refers to a ratio of an etching rate of A that is a layer that is not desired to be etched (layer to be served as a mask) to an etching rate of B that is a layer that is desired to be etched. Specifically, “an etching selective ratio of B to A” is specified by the formula of “an etching selective ratio of B to A=an etching rate of B/an etching rate of A”. In addition, “high selective ratio” means that a value of the selective ratio defined above is large as compared with that of a comparison target. The etching selective ratio of the absorber film 4 to the etching mask film is preferably 1.5 or more, and more preferably 3 or more.

Examples of the material having a high etching selective ratio of the absorber film 4 to the etching mask film include a chromium material and a chromium compound material. Therefore, in a case where the absorber film 4 is etched with a fluorine-based gas, a chromium material and a chromium compound material can be used. Examples of the chromium compound include a material containing Cr and at least one element selected from N, O, C, and H. In addition, the absorber film 4 is etched with a chlorine-based gas substantially containing no oxygen, a silicon material and a silicon compound material can be used as the etching mask film. Examples of the silicon compound include a material containing Si and at least one element selected from N, O, C and H and a material such as metallic silicon containing a metal in silicon or a silicon compound (metal silicide) and a metal silicon compound (metal silicide compound). Examples of the metal silicon compound include a material containing metal, Si, and at least one element selected from N, O, C, and H.

The film thickness of the etching mask film is desirably 3 nm or more from the viewpoint of obtaining a function as an etching mask for accurately forming the transfer pattern on the absorber film 4. In addition, the film thickness of the etching mask film is desirably 15 nm or less from the viewpoint of reducing the film thickness of a resist film 11.

<<Back Surface Conductive Film>>

On a side of the second main surface (back surface) of the substrate 1 (a side opposite to a surface on which the multilayer reflective film 2 is formed), the back surface conductive film 5 for electrostatic chuck is generally formed. An electrical characteristic (sheet resistance) required of the back surface conductive film 5 for electrostatic chuck is usually 100 Ω/square or less. A method of forming the back surface conductive film 5 is, for example, a magnetron sputtering method or an ion beam sputtering method using a target of metal chromium, tantalum, and the like or an alloy thereof.

A material containing chromium (Cr) for the back surface conductive film 5 is preferably a Cr compound containing Cr and at least one substance selected from boron, nitrogen, oxygen, and carbon. Examples of the Cr compound include CrN, CrON, CrCN, CrCON, CrBN, CrBON, CrBCN, and CrBOCN.

As a material containing tantalum (Ta) for the back surface conductive film 5, Ta (tantalum), an alloy containing Ta, or a Ta compound containing at least one from boron, nitrogen, oxygen, and carbon in either of Ta or the alloy containing Ta is preferably used. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, and TaSiCON.

As a material containing tantalum (Ta) or chromium (Cr), an amount of nitrogen (N) present in the surface layer thereof is preferably small. Specifically, nitrogen content in the surface layer of the back surface conductive film 5 of the material containing tantalum (Ta) or chromium (Cr) is preferably less than 5 atomic %, and more preferably has substantially no nitrogen. This is because in the back surface conductive film 5 of the material containing tantalum (Ta) or chromium (Cr), the lower the nitrogen content in the surface layer is, the higher the wear resistance is.

The back surface conductive film 5 preferably includes a material containing tantalum and boron. Since the back surface conductive film 5 includes a material containing tantalum and boron, a conductive film 23 having wear resistance and chemical resistance can be obtained. In a case where the back surface conductive film 5 contains tantalum (Ta) and boron (B), B content is preferably 5 to 30 atomic %. The ratio of Ta and B (Ta:B) in the sputtering target used for forming the conductive film 23 is preferably from 95:5 to 70:30.

The thickness of the back surface conductive film 5 is usually 10 nm to 200 nm though there is no particular limitation on the thickness as long as a function for an electrostatic chuck is satisfied. In addition, the back surface conductive film 5 further include a function of stress adjustment on the side of the second main surface of the mask blank 100. That is, an adjustment is made so that because of the presence of the back surface conductive film 5, the flat reflective mask blank 100 can be obtained in balance with the stress from various films formed on the side of the first main surface.

In addition, an intermediate layer may be provided on the back surface conductive film 5 on the side of the substrate 1. The intermediate layer can have a function of improving adhesion between the substrate 1 and the back surface conductive film 5 and a function of suppressing entry of hydrogen from the substrate 1 into the back surface conductive film 5. In addition, the intermediate layer can have a function of suppressing vacuum ultraviolet light and ultraviolet light (wavelength: 130 to 400 nm) called out-of-band light in a case where EUV light is used as an exposure source from being transmitted through the substrate 1 and reflected by the back surface conductive film 5. Examples of a material of the intermediate layer include Si, SiO₂, SiON, SiCO, SiCON, SiBO, SiBON, Cr, CrN, CrON, CrC, CrCN, CrCO, CrCON, Mo, MoSi, MoSiN, MoSiO, MoSiCO, MoSiON, MoSiCON, TaO, TaON and TaBO The thickness of the intermediate layer is preferably 1 nm or more, more preferably 5 nm or more, and still more preferably 10 nm or more.

<Reflective Mask and Method of Manufacturing the Same>

A reflective mask 200 is manufactured using a reflective mask blank 100 of the present embodiment. Here, an outline description will be only given, and a detailed description will be given below in Examples with reference to the drawings.

The reflective mask 200 has an absorber pattern 4a in which an absorber film 4 of the reflective mask blank 100 described above is patterned. The reflective mask 200 is manufactured by patterning the absorber film 4 of the reflective mask blank 100 described above by dry etching to form the absorber pattern 4a. According to the reflective mask 200 of the present embodiment, since the shadowing effect can be further reduced, it is possible to obtain the reflective mask 200 that can form the fine and highly accurate absorber pattern 4a on a transfer-receiving substrate 1.

The reflective mask blank 100 is prepared, and a resist film 11 is formed on the absorber film 4 on a first main surface of the reflective mask blank 100 (this is not necessary in a case where the resist film 11 is provided as the reflective mask blank 100). Next, a desired pattern is drawn (exposed) on the resist film 11, and further developed and rinsed to form a predetermined resist pattern 11a.

In the case of manufacturing the reflective mask 200, the resist pattern 11a described above is used as a mask, and the absorber pattern 4a is formed by etching the absorber film 4. Next, the absorber pattern 4a is formed by removing the resist pattern 11a by ashing and/or resist stripper liquid. Finally, wet cleaning using an acidic and/or alkaline aqueous solution is performed.

Examples of an etching gas for the absorber film 4 include a chlorine-based gas such as Cl₂, SiCl₄, CHCl₃ and CCl₄, a mixed gas containing a chlorine-based gas and He at a predetermined ratio, and a mixed gas containing a chlorine-based gas and Ar at a predetermined ratio. In etching the absorber film 4, since the etching gas substantially contains no oxygen, a Ru-based protective film 3 does not have a rough surface. In the present description, “the etching gas substantially contains no oxygen” means that oxygen content in the etching gas is 5 atomic % or less.

Through the above steps, the reflective mask 200 having a small shadowing effect and having a highly accurate and fine pattern can be obtained.

<Method of Manufacturing Semiconductor Device>

The present embodiment is a method of manufacturing a semiconductor device having a step of setting a reflective mask 200 of the present embodiment in an exposure apparatus having an exposure light source that emits EUV light, and transferring a transfer pattern to a resist film formed on a transfer-receiving substrate such as a semiconductor substrate.

By performing EUV exposure using the reflective mask 200 of the present embodiment, a desired transfer pattern based on an absorber pattern 4a on the reflective mask 200 can be formed on the semiconductor substrate while a decrease in accuracy of a transfer dimension due to a shadowing effect can be suppressed. By using the reflective mask 200 of the embodiment, a fine and highly accurate semiconductor device can be manufactured. With various steps such as etching of a film to be processed, formation of an insulating film and a conductive film, introduction of a dopant, or annealing in addition to this lithography step, it is possible to manufacture a semiconductor device on which a desired electronic circuit is formed.

More specifically, an EUV exposure apparatus includes a laser plasma light source that generates EUV light, an illumination optical system, a mask stage system, a reduction projection optical system, a wafer stage system, and vacuum equipment. The light source is provided with a debris trap function, a cut filter that cuts light having a long wavelength other than the exposure light, a vacuum differential pumping facility, and the like. The illumination optical system and the reduction projection optical system each includes a reflection mirror. The reflective mask 200 for EUV exposure is electrostatically attracted by a back surface conductive film 5 formed on a second main surface of the reflective mask 200 and is mounted on a mask stage.

Exposure light (irradiation light) from the EUV light source is emitted the reflective mask 200 normally at an angle of 6 to 8 degrees (incident angle θₓ₀ of a center irradiation light 30 shown in FIG. 5) with respect to a normal line of a main surface of the reflective mask 200 (straight line perpendicular to the main surface) via the illumination optical system. Reflected light from the reflective mask 200 with respect to this incident light (exposure light) is reflected (regularly reflected) in a direction opposite to an incident direction and at the same angle as the incident angle, guided to a reflective projection system usually having a reduction ratio of 1/4, and exposed on a resist on a wafer (semiconductor substrate) mounted on a wafer stage. In the EUV exposure apparatus, at least a place through which EUV light passes is evacuated. When performing exposure, mainstream exposure is scan exposure in which the mask stage and the wafer stage are synchronously scanned at a speed corresponding to the reduction ratio of the reduction projection optical system, and exposure is performed through a slit. After the exposure on the resist, this resist film subjected to the exposure is developed to form a resist pattern on the semiconductor substrate. In the present embodiment, a resist pattern of a fine and highly accurate transfer pattern can be formed on the transfer-receiving substrate by further reducing the shadowing effect of the reflective mask 200. By performing etching or the like using this resist pattern as a mask, for example, a predetermined wiring pattern can be formed on the semiconductor substrate. The semiconductor device is manufactured through such an exposure step, a step of processing a film to be processed, a step of forming an insulating film and a conductive film, a dopant introduction step, an annealing step, and other necessary steps.

### EXAMPLES

Hereinafter, Examples will be described with reference to the drawings. Note that in Examples, the same reference numerals will be used for similar components, and the description thereof will be simplified or omitted.

### Example 1

FIGS. 2A-2D are schematic cross-sectional diagrams of a main part showing a step of manufacturing reflective mask 200 from a reflective mask blank 100.

The reflective mask blank 100 of Example 1 includes a back surface conductive film 5, a substrate 1, a multilayer reflective film 2, a protective film 3, and an absorber film 4. The absorber film 4 of Example 1 includes a single layer of a material of an AlNi alloy (Al:Ni=53:47, atomic ratio). Then, as shown in FIG. 2A, a resist film 11 is formed on the absorber film 4.

First, the substrate 1 used for the reflective mask blank 100 of Example 1 will be described. An SiO₂—TiO₂-based glass substrate that is a low thermal expansion glass substrate of 6025 size (approximately 152 mm×152 mm×6.35 mm) in which both main surfaces that are a first main surface and a second main surface of Example 1 were polished was prepared as the substrate 1. The SiO₂—TiO₂-based glass substrate (substrate 1) was polished by a rough polishing step, a fine polishing step, a local processing step, and a touch polishing step so that the SiO₂—TiO₂-based glass substrate have flat and smooth main surfaces.

Next, the back surface conductive film 5 including a CrN film was formed on the second main surface (back surface) of the SiO₂—TiO₂-based glass substrate (substrate 1) by a magnetron sputtering (reactive sputtering) method under the following conditions. Note that in the present description, a ratio of a mixed gas is volume % of a gas to be introduced.

Conditions for forming the back surface conductive film 5: Cr target, a mixed gas atmosphere of Ar and N₂ (Ar: 90%, N: 10%), and film thickness of 20 nm.

Next, the multilayer reflective film 2 was formed on the main surface (first main surface) of the substrate 1 on a side opposite to a side on which the back surface conductive film 5 was formed. The multilayer reflective film 2 formed on the substrate 1 was a periodic multilayer reflective film including Mo and Si in order to be the multilayer reflective film 2 suitable for EUV light having a wavelength of 13.5 nm. The multilayer reflective film 2 was formed by using an Mo target and an Si target and alternately layering a Mo layer and a Si layer on the substrate 1 by an ion beam sputtering method in an Ar gas atmosphere. First, a Si film was formed with a thickness of 4.2 nm, and then an Mo film was formed with a thickness of 2.8 nm. This formation was counted as one period, and the Si film and the Mo film were layered for 40 periods in a similar manner. Finally, a Si film was formed with a thickness of 4.0 nm and the multilayer reflective film 2 was formed. Here, a building-up period was set to 40 periods, but is not limited to this. The building-up period can be, for example, 60 periods. In a case where the building-up period is set to 60 periods, the number of steps is larger than the number of steps in the case of 40 periods, but reflectance of the multilayer reflective film 2 for EUV light can be increased.

Subsequently, the protective film 3 including an Ru film was formed with a thickness of 2.5 nm by the ion beam sputtering method using an Ru target in the Ar gas atmosphere.

Next, the absorber film 4 including an AlNi film was formed by a direct current (DC) magnetron sputtering method. The AlNi film was formed with a film thickness of 36.6 nm using an AlNi target by reactive sputtering in the Ar gas atmosphere.

When the composition of the AlNi film was measured, an atomic ratio was 53 atomic % for Al and 47 atomic % for Ni. In addition, a refractive index n of the AlNi film in EUV light having a wavelength of 13.5 nm was approximately 0.977, and an extinction coefficient k thereof was approximately 0.049. In addition, a phase difference of EUV light transmitted through the AlNi film when compared with EUV light transmitted through a vacuum was approximately 57 degrees.

Reflectance of the absorber film 4 including the AlNi film at a wavelength of 13.5 nm was 2.4%.

Next, using the reflective mask blank 100 of Example 1, the reflective mask 200 of Example 1 was manufactured.

On the absorber film 4 of the reflective mask blank 100 of Example 1, the resist film 11 was formed with a thickness of 100 nm (FIG. 2A). A desired pattern was drawn (exposed) on this resist film 11, and further developed and rinsed to form a predetermined resist pattern 11a (FIG. 2B). Next, with the resist pattern 11a used as a mask, dry etching of the AlNi film (absorber film 4) was performed using a Cl₂ gas. By this dry etching, an absorber pattern 4a was formed (FIG. 2C).

Thereafter, the resist pattern 11a was removed by ashing or a resist stripper liquid. Finally, wet cleaning using pure water (DIW) was performed. Through the above steps, the reflective mask 200 of Example 1 was manufactured (FIG. 2D). Note that if necessary, a mask defect can be inspected after the wet cleaning, and the mask defect can be corrected appropriately.

The reflective mask 200 manufactured in the present example was set in an EUV exposure apparatus, and EUV exposure was performed on a wafer on which a film to be processed and a resist film were formed on a semiconductor substrate. The incident angle of the exposure light (irradiation light) on the reflective mask 200 was 6 degrees. That is, the irradiation angle θₓ₀ of a center irradiation light 30 in FIG. 5 was set to 6 degrees. Subsequently, after exposure of the resist film 11, the resist film 11 subjected to the exposure was developed to form a resist pattern on the semiconductor substrate on which the film to be processed was formed.

When a resist pattern on the semiconductor substrate manufactured according to Example 1 was analyzed, it was found that a positional shift caused by a phase difference due to a shadowing effect of the absorber pattern 4a of the reflective mask 200 was 1.0 nm.

In addition, this resist pattern was transferred on a film to be processed by etching, and a semiconductor device having desired characteristics was successfully manufactured by being subjected to various steps such as formation of an insulating film, conductive film, introduction of a dopant, or annealing.

### Example 2

In a reflective mask blank 100 of Example 2 includes, an absorber film 4 includes a single layer of a material of an AlCo alloy (Al:Co=46:54, atomic ratio). Components other than that are similar to those of Example 1.

An absorber film 4 including an AlCo film was formed by a DC magnetron sputtering method. The AlCo film was formed with a film thickness of 37.5 nm using an AlCo target by reactive sputtering in an Ar gas atmosphere.

When the composition of the AlCo film was measured, an atomic ratio was 46 atomic % for Al and 54 atomic % for Co. In addition, a refractive index n of the AlCo film in EUV light having a wavelength of 13.5 nm was approximately 0.968, and an extinction coefficient k thereof was approximately 0.047. In addition, a phase difference of EUV light transmitted through the AlCo film when compared with EUV light transmitted through a vacuum was approximately 74 degrees.

Reflectance of the absorber film 4 including the AlCo film of Example 2 at a wavelength of 13.5 nm was 2.2%.

In a manner similar to that in Example 1, a reflective mask 200 of Example 2 was manufactured using the reflective mask blank 100 of Example 2. In addition, in a manner similar to that in Example 1, a resist pattern was formed on a semiconductor substrate using the reflective mask 200 of Example 2.

When the resist pattern was analyzed on the semiconductor substrate manufactured according to Example 2, it was found that a positional shift caused by a phase difference due to the shadowing effect of an absorber pattern 4a of the reflective mask 200 was 1.2 nm.

In addition, this resist pattern was transferred on a film to be processed by etching, and a semiconductor device having desired characteristics was successfully manufactured by being subjected to various steps such as formation of an insulating film, conductive film, introduction of a dopant, or annealing.

### Example 3

In a reflective mask blank 100 of Example 3, as in Example 1, an absorber film 4 includes a single layer of an AlNi alloy material. However, unlike Example 1, an atomic ratio of the AlNi alloy material of the absorber film 4 of Example 3 is 75 atomic % for Al and 25 atomic % for Ni. Components other than that are similar to those of Example 1.

The absorber film 4 including an AlNi film was formed by a DC magnetron sputtering method. The AlNi film was formed with a film thickness of 43.7 nm using an AlNi target having a predetermined composition by reactive sputtering in an Ar gas atmosphere.

When the composition of the AlNi film was measured, an atomic ratio was 74 atomic % for Al and 26 atomic % for Ni. In addition, a refractive index n of the AlNi film in EUV light having a wavelength of 13.5 nm was approximately 0.985, and an extinction coefficient k thereof was approximately 0.042. In addition, a phase difference of EUV light transmitted through the AlNi film when compared with EUV light transmitted through a vacuum was approximately 44 degrees.

Reflectance of the absorber film 4 including the AlNi film of Example 3 at a wavelength of 13.5 nm was 2.1%.

In a manner similar to that in Example 1, a reflective mask 200 of Example 3 was manufactured using the reflective mask blank 100 of Example 3. In addition, in a manner similar to that in Example 1, a resist pattern was formed on a semiconductor substrate using the reflective mask 200 of Example 3.

When the resist pattern on the semiconductor substrate manufactured according to Example 3 was analyzed, it was found that a positional shift due to a phase difference of the absorber film 4 of the reflective mask 200 was 0.8 nm.

In addition, this resist pattern 11a was transferred on a film to be processed by etching, and a semiconductor device having desired characteristics was successfully manufactured by being subjected to various steps such as formation of an insulating film, conductive film, introduction of a dopant, or annealing.

### Comparative Example 1

In a reflective mask blank 100 of Comparative Example 1, an absorber film 4 includes a single layer of a TaBN material. An atomic ratio of the TaBN material of Comparative Example 1 is 75 atomic % for Ta, 12 atomic % for B, and 13 atomic % for N. Components other than that are similar to those of Example 1.

The absorber film 4 including a TaBN film was formed by a DC magnetron sputtering method. The TaBN film was formed with a film thickness of 62 nm using a TaB target having a predetermined composition by reactive sputtering in a mixed gas atmosphere of Ar gas and N₂ gas.

When the composition of the TaBN film was measured, an atomic ratio was 75 atomic % for Ta, 12 atomic % for B, and 13 atomic % for N. In addition, a refractive index n of the TaBN film in EUV light at a wavelength of 13.5 nm was approximately 0.949, and an extinction coefficient k thereof was approximately 0.030. In addition, a phase difference of EUV light transmitted through the TaBN film when compared with EUV light transmitted through a vacuum was approximately 166 degrees.

Reflectance of the absorber film 4 including the TaBN film of Comparative Example 1 at a wavelength of 13.5 nm was 1.4%.

In a manner similar to that in Example 1, a reflective mask 200 of Comparative Example 1 was manufactured using the reflective mask blank 100 of Comparative Example 1. In addition, in a manner similar to that in Example 1, a resist pattern was formed on a semiconductor substrate using the reflective mask 200 of Comparative Example 1.

When the resist pattern was analyzed on the semiconductor substrate manufactured in Comparative Example 1, it was found that a positional shift due to a phase difference of the absorber film 4 of the reflective mask 200 was 3.2 nm. In addition, the film thickness of an absorber pattern was also 62 nm, and could not be less than 60 nm.

From the results of the positional shifts caused by the phase differences of the absorber films 4 of the reflective masks 200 of Examples 1 to 3 and Comparative Example 1 described above, it has become clear that the reflective mask 200 of the present disclosure can further reduce the shadowing effect and the fine and highly accurate transfer pattern can be formed on the transfer-receiving substrate.

### REFERENCE SIGNS LIST

1 Substrate
2 Multilayer reflective film
3 Protective film
4 Absorber film
4a Absorber pattern
5 back surface conductive film
11 Resist film
11a Resist pattern
20 Light source
30 Center Irradiation light
31x, 32x Irradiation light diverging in X direction
31y, 32y Irradiation light diverging in Y direction
33 Irradiation light transmitted through edge
40 Virtual line perpendicular to reflective mask surface
50 Irradiation area
100 Reflective mask blank
200 Reflective mask
θ_{d} Divergence angle (half-width)
θ_{y0}, θₓ₁, θₓ₂ Incident angle of irradiation light in X direction
θ_{y0}, θ_{y1}, θ_{y2} Incident angle of irradiation light in Y direction
C Center of irradiation area
P Irradiation position of exposure light (irradiation light) of exposure light source

1. A reflective mask blank comprising:
a substrate;
a multilayer reflective film on the substrate; and
an absorber film on the multilayer reflective film,
wherein the absorber film includes a first material having a refractive index n of at least 0.99 for EUV light and a second material having an extinction coefficient k of at least 0.035 for EUV light.

2. The reflective mask blank according to claim 1, wherein the absorber film is configured to shift a phase of EUV light transmitted through the absorber film, when compared with a phase of EUV light transmitted through a vacuum for a same distance as a thickness of the absorber film, by not more than 150 degrees.

3. The reflective mask blank according to claim 1, wherein a refractive index n of the absorber film for EUV light is at least 0.955, and an extinction coefficient k of the absorber film for EUV light is at least 0.03.

4. The reflective mask blank according to claim 1, wherein the first material contains at least one selected from aluminum (Al), germanium (Ge), and magnesium (Mg).

5. The reflective mask blank according to claim 1, wherein the second material contains at least one selected from nickel (Ni) and cobalt (Co).

6. The reflective mask blank according to claim 1, wherein the first material is aluminum (Al), and an aluminum (Al) content of the absorber film is 10 to 90 atomic %.

7. A reflective mask comprising:
a substrate;
a multilayer reflective film on the substrate; and
an absorber pattern on the multilayer reflective film,
wherein the absorber pattern includes a first material having a refractive index n of at least 0.99 for EUV light and a second material having an extinction coefficient k of at least 0.035 for EUV light.

8. A method of manufacturing a reflective mask comprising a substrate, a multilayer reflective film on the substrate, and an absorber pattern on the multilayer reflective film, comprising:
forming the absorber pattern by patterning an absorber film,
wherein the absorber film includes a first material having a refractive index n of at least 0.99 for EUV light and a second material having an extinction coefficient k of at least 0.035 for EUV light.

9. A method of manufacturing a semiconductor device, the method comprising a step of setting the reflective mask according to claim 7 in an exposure apparatus having an exposure light source that emits EUV light and transferring a transfer pattern to a resist film formed on a transfer-receiving substrate.

10. The reflective mask according to claim 7, wherein the absorber pattern is configured to shift a phase of EUV light transmitted through the absorber pattern, when compared with a phase of EUV light transmitted through a vacuum for a same distance as a thickness of the absorber pattern, by not more than 150 degrees.

11. The reflective mask according to claim 7, wherein a refractive index n of the absorber pattern for EUV light is at least 0.955, and an extinction coefficient k of the absorber pattern for EUV light is at least 0.03.

12. The reflective mask according to claim 7, wherein the first material contains at least one selected from aluminum (Al), germanium (Ge), and magnesium (Mg).

13. The reflective mask according to claim 7, wherein the second material contains at least one selected from nickel (Ni) and cobalt (Co).

14. The reflective mask according to claim 7, wherein the first material is aluminum (Al), and an aluminum (Al) content of the absorber pattern is 10 to 90 atomic %.

15. The method according to claim 8, wherein the absorber film is configured to shift a phase of EUV light transmitted through the absorber film, when compared with a phase of EUV light transmitted through a vacuum for a same distance as a thickness of the absorber film, by not more than 150 degrees.

16. The method according to claim 8, wherein a refractive index n of the absorber film for EUV light is at least 0.955, and an extinction coefficient k of the absorber film for EUV light is at least 0.03.

17. The method according to claim 8, wherein the first material contains at least one selected from aluminum (Al), germanium (Ge), and magnesium (Mg).

18. The method according to claim 8, wherein the second material contains at least one selected from nickel (Ni) and cobalt (Co).

19. The method according to claim 8, wherein the first material is aluminum (Al), and an aluminum (Al) content of the absorber film is 10 to 90 atomic %.
